(19) United States
(12) Patent Application Publication
(10) Pub. No.: US 2016/0071729 A1
(43) Pub. Date: Mar. 10, 2016

(54) RECTANGULAR NANOSHEET FABRICATION

(71) Applicant: Samsung Electronics Co., Ltd., Gyeonggi-do (KR)

(72) Inventors: Ryan M. Hatcher, Round Rock, TX (US); Robert C. Bowen, Austin, TX (US); Wei-E Wang, Austin, TX (US); Mark S. Rodder, Dallas, TX (US)

(21) Appl. No.: 14/830,622

(22) Filed: Aug. 19, 2015

Related U.S. Application Data
(60) Provisional application No. 62/045,709, filed on Sep. 4, 2014.

(51) Int. Cl. H01L 21/02; H01L 29/78; H01L 29/10; H01L 29/66

(52) U.S. Cl. CPC H01L 21/02664; H01L 21/02474; H01L 21/02483; H01L 21/02461; H01L 21/02463; H01L 21/02524; H01L 21/02538; H01L 29/66795; H01L 29/785; H01L 29/1033; H01L 21/02477; H01L 21/02485

(57) ABSTRACT

Exemplary embodiments provide methods for fabricating a nanosheet structure suitable for field-effect transistor (FET) fabrication. Aspects of exemplary embodiment include selecting an active material that will serve as a channel material in the nanosheet structure, a substrate suitable for epitaxial growth of the active material, and a sacrificial material to be used during fabrication of the nanosheet structure; growing a stack of alternating layers of active and sacrificial materials over the substrate; and selectively etching the sacrificial material, wherein due to the properties of the sacrificial material, the selective etch results in remaining layers of active material having an aspect ratio greater than 1 and substantially a same thickness and atomic smoothness along the entire cross-sectional width of each active material layer perpendicular to current flow.

### CROSS-REFERENCE TO RELATED APPLICATIONS

This application claims the benefit of Provisional Patent Application Ser. No. 62/045,709, entitled “Rectangular Nanosheet Fabrication Method” filed on Sep. 4, 2014, and herein incorporated by reference.

### BACKGROUND

Advanced CMOS nodes require multi-gate architectures in order to achieve sufficient electrostatic control to modulate current in short channels. A multi-sheet nanosheet device is a promising architecture for advanced nodes as it may offer excellent mobility and electrostatic control. In addition, nanosheet architectures may compare favorably to the alternatives because the roughness of the channel/dielectric interface is limited by the precision of broad area epitaxial growth and selective etching instead of, e.g., lithography and etching as is the case for FinFETs. Given that the ability to control epitaxial growth over broad areas at the atomic scale (i.e. layer by layer) already exists, the atomic smoothness of nanosheet devices will depend upon the selectivity of the etch between the active material and the sacrificial material in a superlattice.

Conventional nanosheets fabrication includes growing active and sacrificial Si/SixGe1−x superlattices, etching trenches, forming sidewall and or dummy gates for structural support and then removing the SixGe1−x layers with respect to Si for one type of MOSFET (e.g. n−type), or for both types of MOSFETs (n−type and p−type), with a selective etch process. Similarly, the Si layers can be removed with respect to SixGe1−x for another type of MOSFET (e.g. p−type) if desired, also with a selective etch process. However, the selectivity between Si and SixGe1−x is limited due to the chemical similarity.

Due to the chemical similarity, conventional fabricated nanosheet structures are rounded at least at the outer edge portions of the nanosheet, i.e., ellipsoidal in shape for typical nanosheet structures having an aspect ratio greater than 2. This is not desirable for advanced CMOS devices due to the degradation of mobility in at least these outer edge portions of the nanosheet structures since mobility can decrease as nanosheet thickness decreases.

### BRIEF SUMMARY

The exemplary embodiment provides methods and systems fabricating a rectangular nanosheet structure suitable for field-effect transistor (FET) fabrication. Aspects of exemplary embodiment include selecting an active material that will serve as a channel material in the nanosheet structure, a substrate suitable for epitaxial growth of the active material, and a sacrificial material to be used during fabrication of the nanosheet structure; growing a stack of alternating layers of active and sacrificial materials over the substrate; and selectively etching the sacrificial material, wherein due to the properties of the sacrificial material, the selective etch results in remaining layers of active material having an aspect ratio greater than 1 and substantially a same thickness and atomic smoothness along the entire cross-sectional width of each active material layer perpendicular to current flow.

In a further embodiment, the sacrificial material has properties including: a close lattice match to the active material; admits high quality growth on the active material and vice versa; and a chemical dissimilarity from the active material sufficient to enable highly selective etches.

BRIEF DESCRIPTION OF SEVERAL VIEWS OF THE DRAWINGS

These and/or other features and utilities of the present general inventive concept will become apparent and more readily appreciated from the following description of the embodiments, taken in conjunction with the accompanying drawings of which:

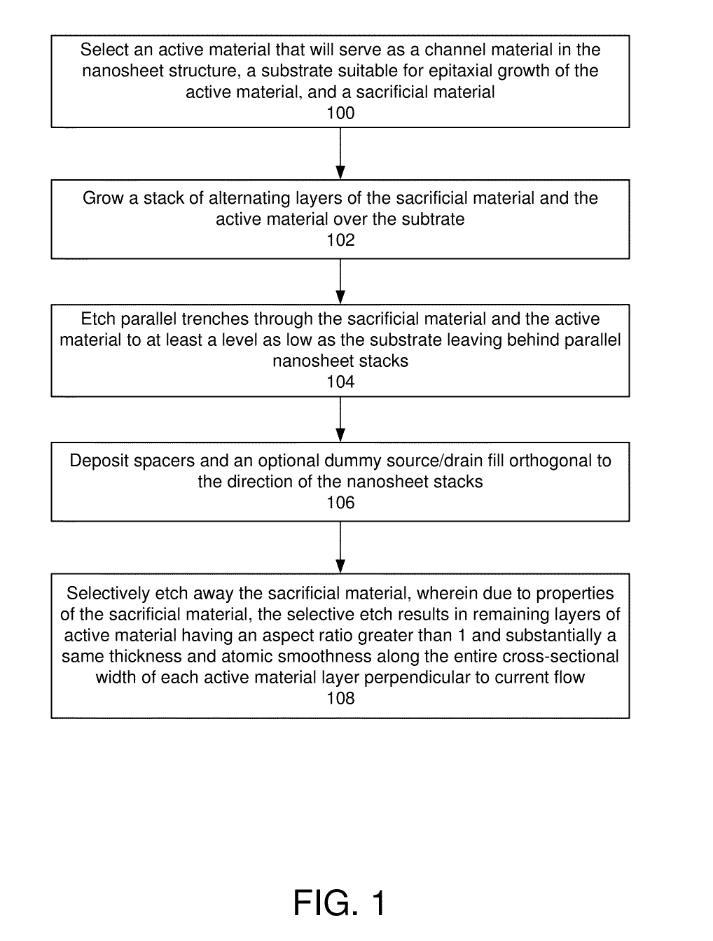

FIG. 1 is a flow block diagram illustrating an exemplary embodiment of a process for fabricating an FET using a rectangular a nanosheet;

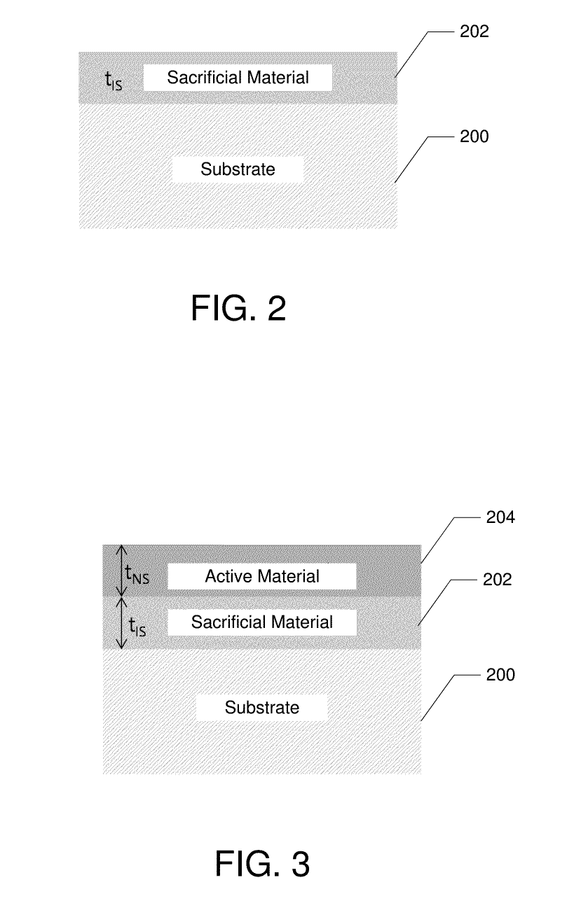

FIG. 2 is a block diagram illustrating the sacrificial material grown on a substrate;

FIG. 3 is a block diagram illustrating the layer of active material grown on the layer of sacrificial material;

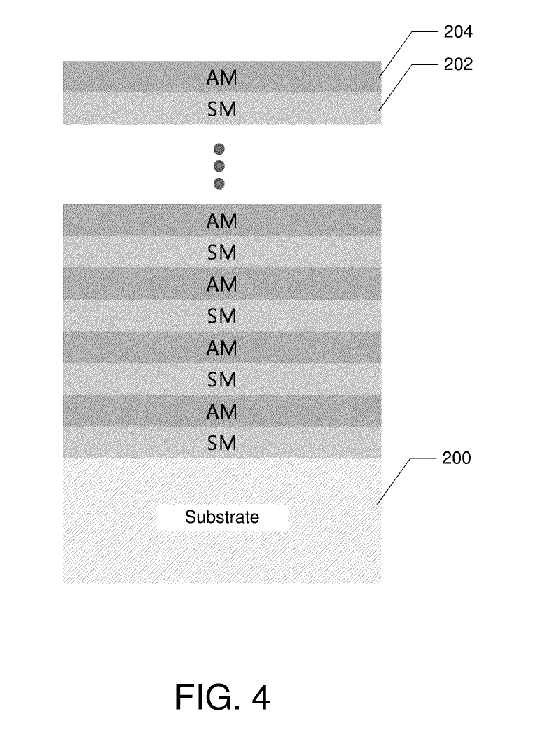

FIG. 4 is a block diagram showing an example stack of alternating layers of sacrificial and active materials;

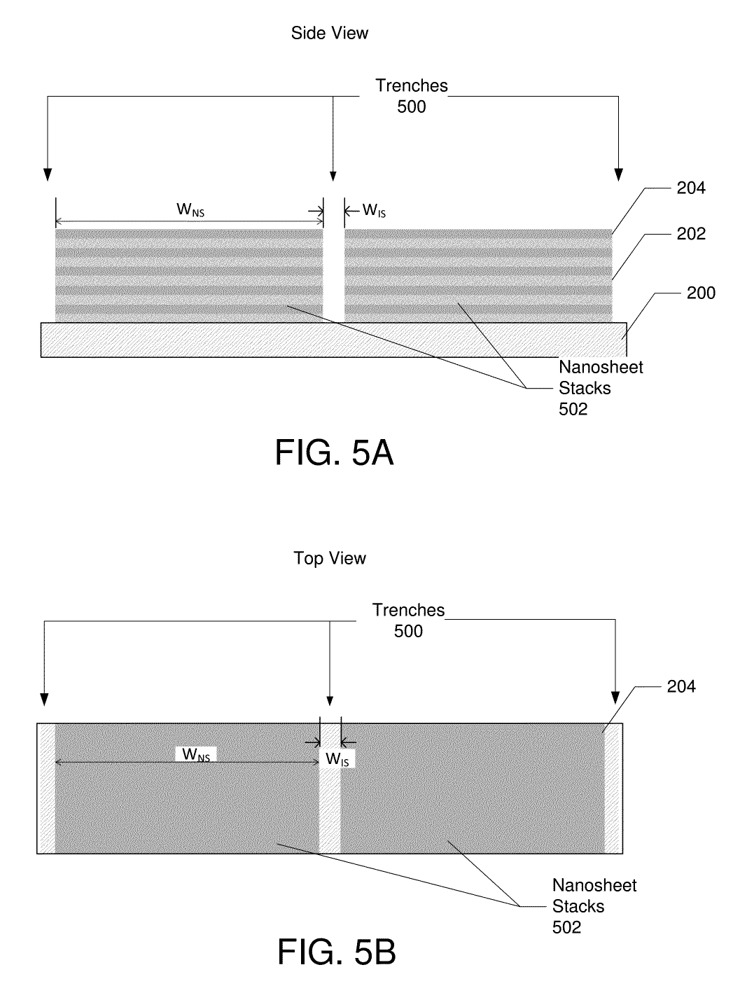

FIGS. 5A and 5B are block diagrams showing a side and top views, respectively, of the stack of alternating layers of sacrificial and active materials and on the substrate after etching of the channel(s);

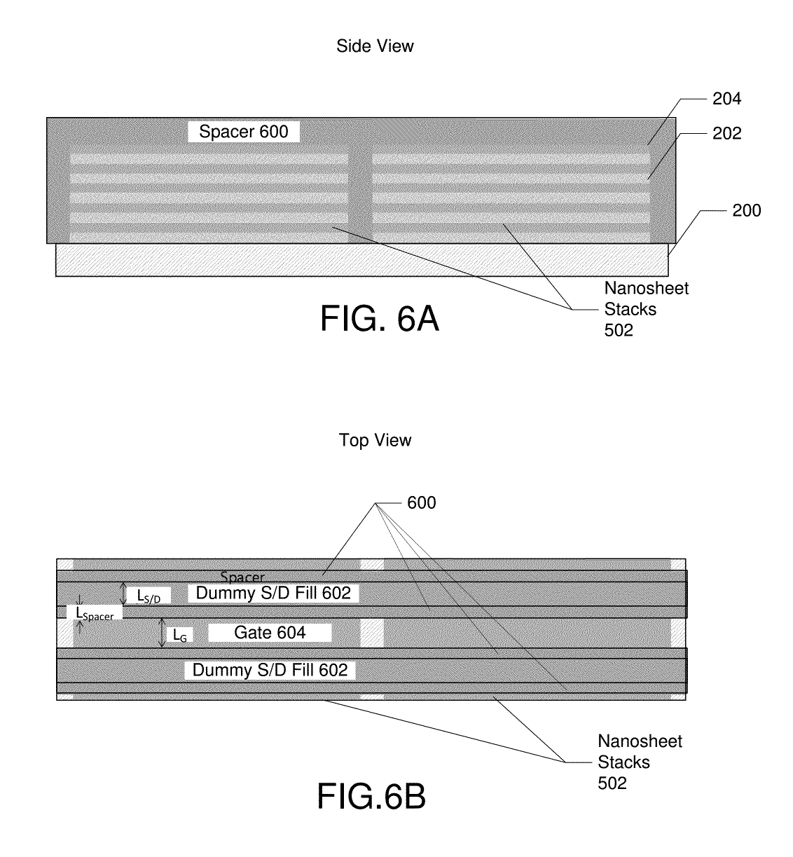

FIGS. 6A and 6B are block diagrams showing a side and top views, respectively, of the stack of alternating layers of sacrificial and active materials;

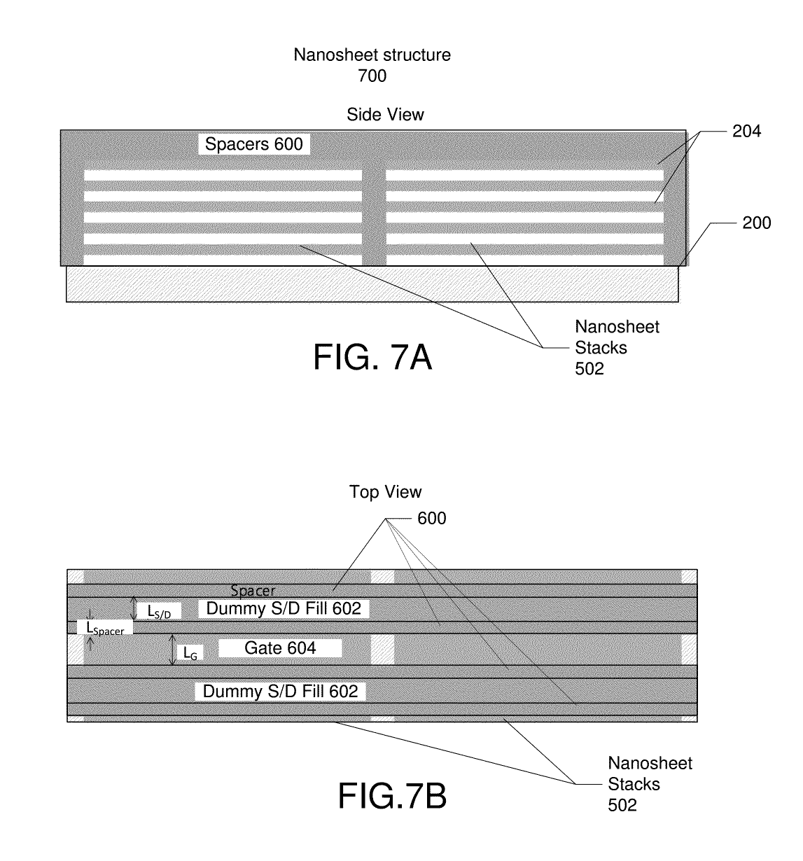

FIGS. 7A and 7B are block diagrams showing a side and top views, respectively, of the rectangular nanosheet structure.

### DETAILED DESCRIPTION

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

Advantages and features of the present invention and methods of accomplishing the same may be understood more readily by reference to the following detailed description of embodiments and the accompanying drawings. The present general inventive concept may, however, be embodied in many different forms and should not be construed as being limited to the embodiments set forth herein. Rather, these embodiments are provided so that this disclosure will be thorough and complete and will fully convey the concept of the general inventive concept to those skilled in the art, and the present general inventive concept will only be defined by the appended claims. In the drawings, the thickness of layers and regions are exaggerated for clarity.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

The exemplary embodiments provide a method for fabricating a rectangular nanosheet structure suitable for advanced CMOS devices, and more particularly to a method for fabricating a FET using a rectangular nanosheet. The nanosheet fabrication includes growing a superlattice of nanosheets comprising a stack of alternating layers of active and sacrificial nanosheet materials, and then selectively etching the sacrificial material such that the active material remains in the final structure and serves as a channel material. It is noted that the terms “active” and “channel” may be used interchangeably throughout this disclosure. Additional subtractive/etch steps may follow disposition of supporting structures such as spacers and/or dummy fills. Due to the type of sacrificial material chosen and its properties relative to the active material, a highly selective etch of the sacrificial material may be performed resulting in the remaining layers of active material having high aspect ratios and substantially the same thickness and atomic smoothness along the entire cross-sectional width of each active material layer perpendicular to current flow. Stated another way, the selective etch process results in the layers of active material having substantially rectangular cross-sections, i.e., inner and outer edge portions that are substantially of the same thickness. Such a nanosheet structure is suitable for advanced CMOS devices with nearly atomically smooth interfaces and without a rounded shape at the outer edge portions of the nanosheet.

FIG. 1 is a flow block diagram illustrating an exemplary embodiment of a process for fabricating an FET using rectangular a nanosheet. The process may begin by selecting an active material that will serve as a channel material in the nanosheet structure, a substrate suitable for epitaxial growth of the active material, and a sacrificial material to be used during fabrication of the nanosheet structure (block 100).

According to the exemplary embodiment, both the active material and the sacrificial material are substantially crystalline and the selected active material may comprise silicon (Si); silicon (Si) and germanium (Ge); or germanium (Ge). In one embodiment, the layers of the active material may be comprised of a III-V or II-VI material.

In one embodiment, the selected sacrificial material preferably has the following three properties: 1) a relatively close lattice match (i.e. within 1-2%) to the active material; 2) admits high quality growth (i.e., defect density <1e4 cm⁻²) on the active material and vice versa; and 3) a chemical dissimilarity from the active material sufficient to enable etches with a selectivity >5:1. Another optional property is the ability to alloy the sacrificial material in order to choose a desired lattice constant. This optional property would be desirable for certain instantiations of strain engineering for example.

In one embodiment, sufficient chemical dissimilarity may be achieved by the active material comprising Group IV atoms, and the sacrificial material comprising of Group II-VI or III-V atoms. In another embodiment, sufficient chemical dissimilarity may be achieved by the active material comprising fully covalent Group IV materials, and the sacrificial material having ionic or polar character in their bonds.

According to one exemplary embodiment, the selected sacrificial material may comprise Zinc sulfide (ZnS), which has a lattice mismatch of only 0.4% compared to the active material, silicon. Known methods exist for high quality epitaxial growth of Si on ZnS (or ZnS on Si), using As as a passivation layer. ZnS satisfies the three requirements for the sacrificial material described above. In one embodiment, the sacrificial material may be comprised of a group IV material or alloy.

Thus in one embodiment, the sacrificial material may comprises at least one of: Zinc sulfide (ZnS), zinc selenide (ZnSe), beryllium sulfide (BeS), or beryllium selenide (BeSe), gallium phosphide (GaP), aluminum phosphide (AlP), gallium arsenide (GaAs), aluminum arsenide (AlAs), gallium phosphide arsenide alloy (GaPₓAs₁₋ₓ), aluminum phosphide arsenide alloy (AlPₓAs₁₋ₓ), or a rare earth oxide including neodymium oxide (Nd₂O₃), gadolinium oxide (Gd₂O₃), samarium oxide (Sm₂O₃), dysprosium oxide (Dy₂O₃), erbium oxide (Er₂O₃), or europium oxide (Eu₂O₃).

Once the desired materials are selected, the process includes growing a stack of alternating layers of the sacrificial material and the active material over the substrate (block 102).

Either a layer of the sacrificial material or the active material may be grown on the substrate first. If the layer of the sacrificial material is grown first, the thickness of this layer is preferably equal to a desired inter-sheet distance, t_{IS}. FIG. 2 is a block diagram illustrating the sacrificial material 202 grown on a substrate 200 to a thickness of t_{IS}.

The layer of active material that is subsequently grown on the sacrificial material may have a thickness that is preferably equal to a desired sheet thickness, t_{NS}. FIG. 3 is a block diagram illustrating the layer of active material 204 grown on the layer of sacrificial material 202 to a thickness of t_{NS}.

The number of layers of the sacrificial material and the active material grown to provide the nanosheets depends on the specific application. FIG. 4 is a block diagram showing an example stack of alternating layers of sacrificial and active materials 202 and 204 grown over the substrate 200.

Referring again to FIG. 1, the process further includes etching parallel trenches through the stack of sacrificial materials and the active materials to at least a level as low as the substrate leaving behind parallel nanosheet stacks (block 104).

FIGS. 5A and 5B are block diagrams showing a side and top views, respectively, of the stack of alternating layers of sacrificial and active materials 202 and 204 on the substrate 200 after etching of the trench(es) 500. In one embodiment, a width of the trenches 500 is equal to a desired inter-sheet distance W_{IS}. As used herein, the trench etching results in the formation of nanosheet stacks 502 comprising some number of layers of active and sacrificial materials. The width between the trenches 500 should be equal to a desired active nanosheets width W_{NS}. In the final structure, current transport will be through the layers of active materials parallel to the trenches—i.e., into or out of the page in FIG. 5A and up or down in FIG. 5B. The width of a single nanosheet stack 502 may also be determined by a desired effective width and desired electrostatic properties (including short-channel effect, DIBL) of each active nanosheet. By way of example, the width of each of the active nanosheets 502 may be generally in any of the ranges 40-80 nm, 20-40 nm, and 5-20 nm.

Referring again to FIG. 1, after the trenches are etched leaving the nanosheets of desired width, the process further includes depositing spacers and an optional dummy source/drain fill orthogonal to the direction of the nanosheet stacks (block 106).

FIGS. 6A and 6B are block diagrams showing side and top views, respectively, of the stack of alternating layers of sacrificial and active materials 202 and 204 on the substrate 200 after depositing a spacer 600 and an optional dummy source/drain (S/D) fill 602 orthogonal to the direction of the nanosheet stacks. In one embodiment, the layers of active materials 204 in the nanosheet stacks 502 may be surrounded on four sides by a dielectric and gate material resulting in a gate-all-around-structure. In an alternative embodiment, the layers of active materials 204 in the nanosheet stacks 502 may be surrounded on three sides by a dielectric and gate material resulting in a tri-gate structure.

In the direction of transport, the gate length L_{G}, width of the spacers 600 L_{Spacer} and the length of the dummy source/drain fills 602 L_{S/D} may be determined by the desired dimensions of the final devices. The dummy S/D fill 602 is optional because it may or may not be needed for structural stability after the etching of the sacrificial material or for other process related reasons (e.g. gate first or gate last, etc. . .).

Referring again to FIG. 1, after depositing spacers, the process further includes selectively etching away the sacrificial material, wherein due to properties of the sacrificial material, the selective etch results in remaining layers of active material having an aspect ratio greater than 1 and substantially a same thickness and atomic smoothness along the entire cross-sectional width of each active material layer perpendicular to current flow (block 108).

FIGS. 7A and 7B are block diagrams showing a side and top views, respectively, of the rectangular nanosheet structure 700. According to the exemplary embodiment, the nanosheet structure 700 comprises stacked thin layers of active material 204 and spacers 600. A thin empty space is located between adjacent layers that was previously occupied by a sacrificial material, where the sacrificial material was removed selected to the active material by selective etch. The layers of active material 204 are supported on the sides by the spacer material in order to keep the nanosheets from collapsing during the selective etch process.

According to the exemplary embodiments, due to the properties of the sacrificial material relative to the active material, the selective etch results in remaining layers of active nanosheets having high aspect ratios and substantially the same thickness and atomic smoothness along the entire cross-sectional width of each active material layer perpendicular to current flow. In one embodiment, the same thickness means having a thickness variation in the range of less than or equal to 10% from a nominal thickness. In another embodiment, the same thickness means having a thickness variation in the range of less than or equal to 5% from the nominal thickness. The phrase “atomic smoothness” is well-known in the art and consistent with a high selectivity between layers of active and sacrificial nanosheet materials.

One aspect of the exemplary embodiments is selecting a sacrificial material for which an extremely high selectivity etch can be implemented resulting from sufficient chemical dissimilarity of the active and sacrificial material, which in turn allows creation of the layers of active material with desired high aspect ratios of width/height of greater than 1. In one embodiment, the aspect ratio of the active material is significantly greater than 2, such as greater than or equal to 5, or greater than or equal to 10. In one embodiment, the selective etch has a selectivity greater than 5:1, and more specifically greater than 50:1.

The selective etch results in nanosheets of active material 204 having a non-rounded, orthogonal shape on outer edges and along the surface of the active material nanosheets. The resulting nanosheet FET thus has high and/or similar mobility along the entire surface of the active material nanosheets with limited degradation at the outer edges of the nanosheet structure.

In one embodiment, the nanosheet structure 700 may be used to fabricate nanosheet FETs that are used a scaled low-power high-performance circuit, with each nanosheet FET comprises a nanosheet structure 700 of stacked and spaced nanosheet layers where each layer comprises of one or more active nanosheets, each active nanosheet has a high aspect ratio and substantially the same thickness and atomic smoothness along the entire cross-sectional width of a nanosheet perpendicular to current flow, the active nanosheet having a high aspect ratio. As described above, the nanosheet structure results from removing sacrificial nanosheet material selective to the active nanosheet material by a selective.

The exemplary embodiments provide the following advantages over selectively etching conventional Si/SiGe structures. One advantage is the ability to fabricate desired high to extremely high aspect ratio nanosheet structures having substantially a rectangular, not ellipsoidal, cross section perpendicular to current flow. An example of an extremely high aspect ratio nanosheet structure is with nanosheets having a sheet-to sheet distance on the order of 10 nm but where the sheet width is on the order of 40-80 nm wide. Because Si and SiGe are chemically similar, the selectivity of any known etch is too small to enable the fabrication of high aspect ratio nanosheet structures with rectangular cross sections. When the selectivity of the etch is too low to support the desired aspect ratio of the structure, the layers end up being ellipsoidal in cross-section and suboptimal as devices since the exposure to the etch is longer the further from the center.

A second advantage is the ability to fabricate structures with large area interfaces that are nearly epitaxially smooth. Smooth surfaces are desirable for gate interfaces (less SRS, traps, and the like). The third advantage is the ability to engineer both compressive and tensile strain in the active material. By choice of different sacrificial materials (alloying or different materials altogether), one can choose to impose compressive or tensile stress on the active material at an interface. For conventional Si/SiGe interfaces, the SiGe can only impose tensile stress on the Si.

A method and system for fabricating a rectangular nanosheet structure has been disclosed. The present invention has been described in accordance with the embodiments shown, and there could be variations to the embodiments, and any variations would be within the spirit and scope of the present invention. Accordingly, many modifications may be made by one of ordinary skill in the art without departing from the spirit and scope of the appended claims.

We claim:

1. A method for fabricating a rectangular nanosheet structure, comprising:
selecting an active material that will serve as a channel material in the nanosheet structure, a substrate suitable for epitaxial growth of the active material, and a sacrificial material to be used during fabrication of the nanosheet structure;
growing a stack of alternating layers of active and sacrificial materials over the substrate; and
selectively etching the sacrificial material, wherein due to properties of the sacrificial material, the selective etch results in remaining layers of active material having an aspect ratio greater than 1 and substantially a same thickness and atomic smoothness along the entire cross-sectional width of each active material layer perpendicular to current flow.

2. The method of claim 1, wherein the sacrificial material has properties including: a close lattice match to the active material; admits high quality growth on the active material and vice versa; and a chemical dissimilarity from the active material sufficient to enable highly selective etches.

3. The method of claim 2, wherein sufficient chemical dissimilarity is achieved by the active material comprising Group IV atoms, and the sacrificial material comprising Group II-VI or III-V atoms.

4. The method of claim 2, wherein sufficient chemical dissimilarity is achieved by the active material comprising fully covalent Group IV materials, and the sacrificial material having ionic or polar character in their bonds.

5. The method of claim 1, wherein the active material comprises at least one of silicon (Si); silicon (Si) and germanium (Ge); germanium (Ge); or a III-V or II-VI material.

6. The method of claim 5, wherein the sacrificial material comprises at least one of Zinc sulfide (ZnS), zinc selenide (ZnSe), beryllium sulfide (BeS), or beryllium selenide (BeSe), gallium phosphide (GaP), aluminum phosphide (AlP), gallium arsenide (GaAs), aluminum arsenide (AlAs), gallium phosphide arsenide alloy (GaPxAs1−x), aluminum phosphide arsenide alloy (AlPxAs1−x), or a rare earth oxide including neodymium oxide (Nd2O3), gadolinium oxide (Gd2O3), samarium oxide (Sm2O3), dysprosium oxide (Dy2O3), erbium oxide (Er2O3), or europium oxide (Eu2O3).

7. The method of claim 1, wherein the aspect ratio of the active material is significantly greater than 2.

8. The method of claim 1, wherein the aspect ratio the active material is greater than or equal to 5.

9. The method of claim 1, wherein the aspect ratio the active material is greater than or equal to 10.

10. The method of claim 1, wherein the selective etch has a selectivity greater than 5:1.

11. The method of claim 1, wherein the layers of active material have a thickness variation in the range of less than or equal to 10% from a nominal thickness.

12. The method of claim 1, wherein the layers and of active material have a thickness variation in the range of less than or equal to 5% from a nominal thickness.

13. The method of claim 1, further comprising: etching parallel trenches through the sacrificial material and the active material to at least a level as low as the substrate, leaving behind parallel nanosheet stacks comprising layers of the active and sacrificial materials.

14. The method of claim 13, wherein the width of each of the active nanosheets may be in at least one range of 40-80 nm, 20-40 nm, and 5-20 nm.

15. The method of claim 13, further comprising: depositing spacers and a dummy source/drain fill orthogonal to the direction of the nanosheet stacks.

16. The method of claim 15, wherein the active nanosheets are surrounded on four sides by a dielectric and gate material resulting in a gate-all-around-structure.

17. The method of claim 15, wherein the active nanosheets are surrounded on three sides by a dielectric and gate material resulting in a tri-gate structure.

18. A field effect transistor (FET), comprising:
a nanosheet structure of stacked and spaced nanosheet layers, wherein each layer comprises of one or more active nanosheets, each active nanosheet having a high aspect ratio and substantially a same thickness and atomic smoothness along the entire cross-sectional width of a nanosheet perpendicular to current flow; and
wherein the nanosheet structure results from removing sacrificial nanosheet material selective to the active nanosheet material by a selective etch, wherein due to properties of the sacrificial nanosheet material, the selective etch results in the nanosheet layers having an aspect ratio greater than 1 and substantially a same thickness and atomic smoothness along the entire cross-sectional width of each of the active nanosheets perpendicular to current flow.

19. The FET of claim 18, wherein the sacrificial material has properties including: a close lattice match to the active material; admits high quality growth on the active material and vice versa; and a chemical dissimilarity from the active material sufficient to enable highly selective etches.

20. The FET of claim 19, wherein sufficient chemical dissimilarity is achieved by the active material comprising Group IV atoms, and the sacrificial material comprising Group II-VI or III-V atoms.

21. The FET of claim 19, wherein sufficient chemical dissimilarity is achieved by the active material comprising fully covalent Group IV materials, and the sacrificial material having ionic or polar character in their bonds.

22. The FET of claim 18, wherein the active material comprises at least one of silicon (Si); silicon (Si) and germanium (Ge); germanium (Ge); or a III-V or II-VI material.

23. The FET of claim 21, wherein the sacrificial material comprises at least one of: Zinc sulfide (ZnS), zinc selenide (ZnSe), beryllium sulfide (BeS), or beryllium selenide (BeSe), gallium phosphide (GaP), aluminum phosphide (AlP), gallium arsenide (GaAs), aluminum arsenide (AlAs), gallium phosphide arsenide alloy (GaPₓAs_{131 x}), aluminum phosphide arsenide alloy (AlPₓAs₁₋ₓ), or a rare earth oxide including neodymium oxide (Nd₂O₃), gadolinium oxide (Gd₂O₃), samarium oxide (Sm₂O₃), dysprosium oxide (Dy₂O₃), erbium oxide (Er₂O₃), or europium oxide (Eu₂O₃).

24. The FET of claim 18, wherein the aspect ratio of the active material is significantly greater than 2.

25. The FET of claim 18, wherein the aspect ratio the active material is greater than or equal to 5.

26. The FET of claim 18, wherein the aspect ratio the active material is greater than or equal to 10.

27. The FET of claim 18, wherein the selective etch has a selectivity greater than 5:1.

28. The FET of claim 18, wherein a width of each of the active nanosheets may be in at least one range of 40-80 nm, 20-40 nm, and 5-20 nm.
